(19) United States
(12) Patent Application Publication
(10) Pub. No.: US 2024/0396507 A1
(43) Pub. Date: Nov. 28, 2024

(54) Amplifier circuit

(71) Applicant: REALTEK SEMICONDUCTOR CORPORATION, HSINCHU (TW)

(72) Inventor: SHIH-HSIUNG HUANG, Hsinchu (TW)

(21) Appl. No.: 18/668,550

(22) Filed: May 20, 2024

(30) Foreign Application Priority Data
May 26, 2023 (TW) 112119730

(51) Int. Cl. H03F 3/16

(52) U.S. Cl. CPC H03F 3/16

(57) ABSTRACT

An amplifier circuit includes four transistors, four switches, a capacitor, and a reference voltage generation circuit. One terminal of the capacitor is coupled to a first reference voltage, and the other terminal of the capacitor is coupled to a second reference voltage. The reference voltage generation circuit is coupled to the input terminals or the output terminals of the amplifier circuit and generates the first reference voltage and/or the second reference voltage according to the input voltages or the output voltages of the amplifier circuit.

### BACKGROUND OF THE INVENTION

### 1. Field of the Invention

The present invention generally relates to amplifiers, and, more particularly, to dynamic amplifiers.

### 2. Description of Related Art

Because dynamic amplifiers do not require a current source to provide a fixed direct current (DC) current, there is no consumption of static current. Furthermore, because the current source requires a threshold voltage to conduct, and the process voltage for complementary metal-oxide-semiconductor (CMOS) technology is decreasing, this threshold voltage limits the swing of the amplifier's output signal. Based on the above reasons, amplifiers such as dynamic amplifiers that do not require static current and have relatively large output swings have recently been widely used in circuit systems. Therefore, improving the performance of dynamic amplifiers has become an important issue in this technical field.

### SUMMARY OF THE INVENTION

In view of the issues of the prior art, an object of the present invention is to provide an amplifier circuit, so as to make an improvement to the prior art.

According to one aspect of the present invention, an amplifier circuit is provided. The amplifier circuit has a first input terminal, a second input terminal, a first output terminal, a second output terminal, a first node, a second node, a third node, and a fourth node, and respectively receives a first input voltage and a second input voltage through the first input terminal and the second input terminal. The amplifier circuit includes a first transistor, a second transistor, a third transistor, a fourth transistor, a first capacitor, a first switch, a second switch, a third switch, a fourth switch, and a reference voltage generation circuit. The first transistor has a first terminal, a second terminal, and a first control terminal, wherein the first terminal is coupled to the first node, the second terminal is coupled to the second output terminal, and the first control terminal is coupled to the first input terminal. The second transistor has a third terminal, a fourth terminal, and a second control terminal, wherein the third terminal is coupled to the second node, the fourth terminal is coupled to the second output terminal, and the second control terminal is coupled to the first input terminal. The third transistor has a fifth terminal, a sixth terminal, and a third control terminal, wherein the fifth terminal is coupled to the first node, the sixth terminal is coupled to the first output terminal, and the third control terminal is coupled to the second input terminal. The fourth transistor has a seventh terminal, an eighth terminal, and a fourth control terminal, wherein the seventh terminal is coupled to the second node, the eighth terminal is coupled to the first output terminal, and the fourth control terminal is coupled to the second input terminal. The first capacitor has a ninth terminal and a tenth terminal, wherein the ninth terminal is coupled to the third node, and the tenth terminal is coupled to the fourth node. The first switch is coupled between the third node and a first reference voltage. The second switch is coupled between the fourth node and a second reference voltage. The third switch is coupled between the first node and the third node. The fourth switch is coupled between the second node and the fourth node. The reference voltage generation circuit is coupled to the first input terminal and the second input terminal and configured to generate at least one of the first reference voltage and the second reference voltage according to the first input voltage and the second input voltage.

According to another aspect of the present invention, an amplifier circuit is provided. The amplifier circuit has a first input terminal, a second input terminal, a first output terminal, a second output terminal, a first node, a second node, a third node, and a fourth node, and outputs a first output voltage and a second output voltage through the first output terminal and the second output terminal, respectively. The amplifier circuit includes a first transistor, a second transistor, a third transistor, a fourth transistor, a first capacitor, a first switch, a second switch, a third switch, a fourth switch, and a reference voltage generation circuit. The first transistor has a first terminal, a second terminal, and a first control terminal, wherein the first terminal is coupled to the first node, the second terminal is coupled to the second output terminal, and the first control terminal is coupled to the first input terminal. The second transistor has a third terminal, a fourth terminal, and a second control terminal, wherein the third terminal is coupled to the second node, the fourth terminal is coupled to the second output terminal, and the second control terminal is coupled to the first input terminal. The third transistor has a fifth terminal, a sixth terminal, and a third control terminal, wherein the fifth terminal is coupled to the first node, the sixth terminal is coupled to the first output terminal, and the third control terminal is coupled to the second input terminal. The fourth transistor has a seventh terminal, an eighth terminal, and a fourth control terminal, wherein the seventh terminal is coupled to the second node, the eighth terminal is coupled to the first output terminal, and the fourth control terminal is coupled to the second input terminal. The first capacitor has a ninth terminal and a tenth terminal, wherein the ninth terminal is coupled to the third node, and the tenth terminal is coupled to the fourth node. The first switch is coupled between the third node and a first reference voltage. The second switch is coupled between the fourth node and a second reference voltage. The third switch is coupled between the first node and the third node. The fourth switch is coupled between the second node and the fourth node. The reference voltage generation circuit is coupled to the first output terminal and the second output terminal and configured to generate at least one of the first reference voltage and the second reference voltage according to the first output voltage and the second output voltage.

The technical means embodied in the embodiments of the present invention can solve at least one of the problems of the prior art. Therefore, compared to the prior art, the present invention can improve the performance of the dynamic amplifier.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is a circuit diagram of an amplifier circuit according to an embodiment of the present invention.

FIG. 2 is a circuit diagram of an amplifier circuit according to another embodiment of the present invention.

FIG. 3 is a circuit diagram of an amplifier circuit according to another embodiment of the present invention.

FIG. 4 is a circuit diagram of a reference voltage generation circuit according to an embodiment of the present invention.

FIG. 5 is a circuit diagram of a reference voltage generation circuit according to another embodiment of the present invention.

FIG. 6 is a circuit diagram of a reference voltage generation circuit according to another embodiment of the present invention.

FIG. 7 is a circuit diagram of an amplifier circuit according to another embodiment of the present invention.

FIG. 8 is a circuit diagram of an amplifier circuit according to another embodiment of the present invention.

FIG. 9 is a circuit diagram of an amplifier circuit according to another embodiment of the present invention.

FIG. 10 is a circuit diagram of a reference voltage generation circuit according to an embodiment.

FIG. 11 is a circuit diagram of a reference voltage generation circuit according to another embodiment.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes an amplifier circuit. On account of that some or all elements of the amplifier circuit could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

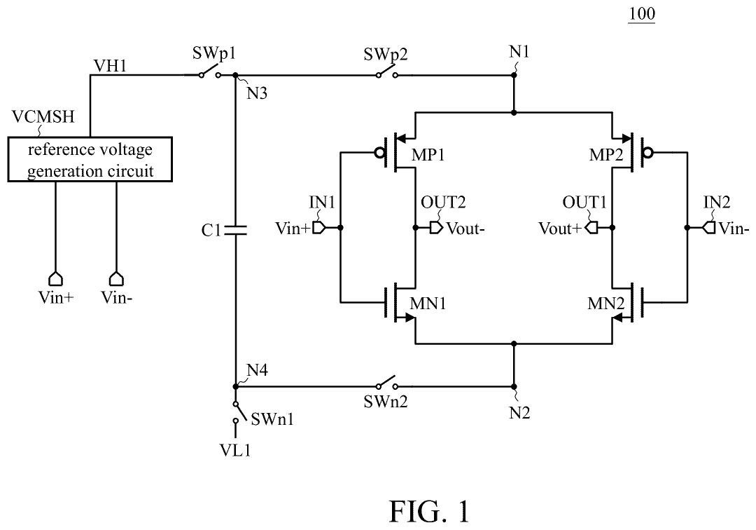

Reference is made to FIG. 1, which is a circuit diagram of an amplifier circuit according to an embodiment of the present invention. The amplifier circuit 100 is a type of dynamic amplifier. The amplifier circuit 100 has an input terminal IN1, an input terminal IN2, an output terminal OUT1, an output terminal OUT2, a node N1, a node N2, a node N3, and a node N4, and includes a transistor MP1, a transistor MN1, a transistor MP2, a transistor MN2, a capacitor C1, a switch SWp1, a switch SWn1, a switch SWp2, a switch SWn2, and a reference voltage generation circuit VCMSH.

It should be noted that in order to focus the discussion below on the technical features of this disclosure, FIG. 1 omits the load capacitors coupled to the output terminals OUT1 and OUT2. As people having ordinary skill in the art are familiar with the purpose of load capacitors, further explanation is omitted for brevity.

The amplifier circuit 100 amplifies the input voltage Vin+ and the input voltage Vin− (inputted to the amplifier circuit 100 through the input terminal IN1 and the input terminal IN2 respectively) to generate the output voltage Vout+ and the output voltage Vout− (outputted through the output terminal OUT1 and the output terminal OUT2 respectively). The input voltage Vin+ and the input voltage Vin− are a pair of differential signals. The output voltage Vout+ and output voltage Vout− are a pair of differential signals.

The transistor MP1 is a P-channel Metal Oxide Semiconductor Transistor (hereinafter referred to as PMOS transistor). The source of the transistor MP1 is coupled or electrically connected to the node N1; the drain of the transistor MP1 is coupled or electrically connected to the output terminal OUT2; the gate (control terminal) of the transistor MP1 is coupled or electrically connected to the input terminal IN1.

The transistor MN1 is an N-channel Metal-Oxide-Semiconductor Transistor (hereinafter referred to as NMOS transistor). The source of the transistor MN1 is coupled or electrically connected to the node N2; the drain of the transistor MN1 is coupled or electrically connected to the output terminal OUT2; the gate of the transistor MN1 is coupled or electrically connected to the input terminal IN1.

The transistor MP2 is a PMOS transistor. The source of the transistor MP2 is coupled or electrically connected to the node N1; the drain of the transistor MP2 is coupled or electrically connected to the output terminal OUT1; the gate of the transistor MP2 is coupled or electrically connected to the input terminal IN2.

The transistor MN2 is an NMOS transistor. The source of the transistor MN2 is coupled or electrically connected to the node N2; the drain of the transistor MN2 is coupled or electrically connected to the output terminal OUT1; the gate of the transistor MN2 is coupled or electrically connected to the input terminal IN2.

One terminal of the switch SWp1 is coupled to the reference voltage generation circuit VCMSH to receive the reference voltage VH1; another terminal of the switch SWp1 is coupled or electrically connected to the node N3 (i.e., one terminal of the capacitor C1).

One terminal of the switch SWn1 is coupled to the reference voltage VL1 (i.e., the switch SWn1 receives the reference voltage VL1); another terminal of the switch SWn1 is coupled or electrically connected to the node N4 (i.e., the other terminal of the capacitor C1).

One terminal of the switch SWp2 is coupled or electrically connected to the node N1; another terminal of the switch SWp2 is coupled or electrically connected to the node N3.

One terminal of the switch SWn2 is coupled or electrically connected to the node N2; another terminal of the switch SWn2 is coupled or electrically connected to the node N4.

The reference voltage generation circuit VCMSH is used to detect the common-mode voltage Vcmi of the input voltage Vin+ and the input voltage Vin−, and generate the reference voltage VH1 according to the common-mode voltage Vcmi. More specifically, when the input voltage Vin+ and the input voltage Vin− increase (i.e., the common-mode voltage Vcmi increases), the reference voltage generation circuit VCMSH generates a greater reference voltage VH1. When the input voltage Vin+ and the input voltage Vin− decrease (i.e., the common-mode voltage Vcmi decreases), the reference voltage generation circuit VCMSH generates a smaller reference voltage VH1. This stabilizes the source-gate voltages (Vsg) of the transistor MP1 and the transistor MP2 (i.e., the fluctuation of the source-gate voltages can be reduced as much as possible), thereby improving the reliability and stability of the amplifier circuit 100. In other words, the amplifier circuit 100 is less susceptible to changes in the common-mode voltage Vcmi, leading to an enhancement in the reliability and stability of the amplifier circuit 100.

The amplifier circuit 100 operates according to a clock. When the clock is at a first level (e.g., a low level), the switches SWp1 and SWn1 are turned on, and the switches SWp2 and SWn2 are turned off. During this phase, the capacitor C1 is being charged.

When the clock is at a second level (e.g., a high level), the switches SWp1 and SWn1 are turned off, and the switches SWp2 and SWn2 are turned on. During this phase, the amplifier circuit 100 amplifies the input voltage Vin+ and the input voltage Vin− to generate the output voltage Vout+ and the output voltage Vout-.

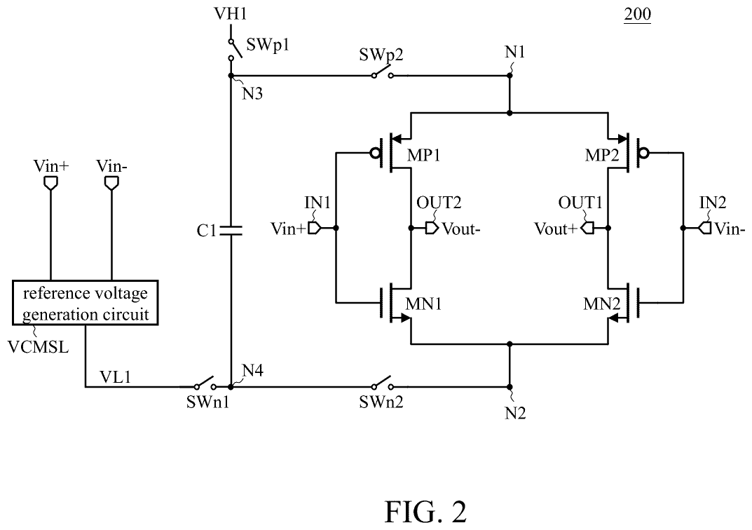

Reference is made to FIG. 2, which is a circuit diagram of an amplifier circuit according to another embodiment of the present invention. The amplifier circuit 200 is a type of dynamic amplifier. The amplifier circuit 200 is similar to the amplifier circuit 100, except that the reference voltage generation circuit VCMSL generates a reference voltage VL1 according to the common-mode voltage Vcmi of the input voltage Vin+ and the input voltage Vin−. This stabilizes the gate-source voltages (Vgs) of the transistor MN1 and the transistor MN2 (i.e., the fluctuation of the gate-source voltages can be reduced as much as possible), thereby improving the reliability and stability of the amplifier circuit 200. In other words, the amplifier circuit 200 is less susceptible to changes in the common-mode voltage Vcmi, leading to an enhancement in the reliability and stability of the amplifier circuit 200.

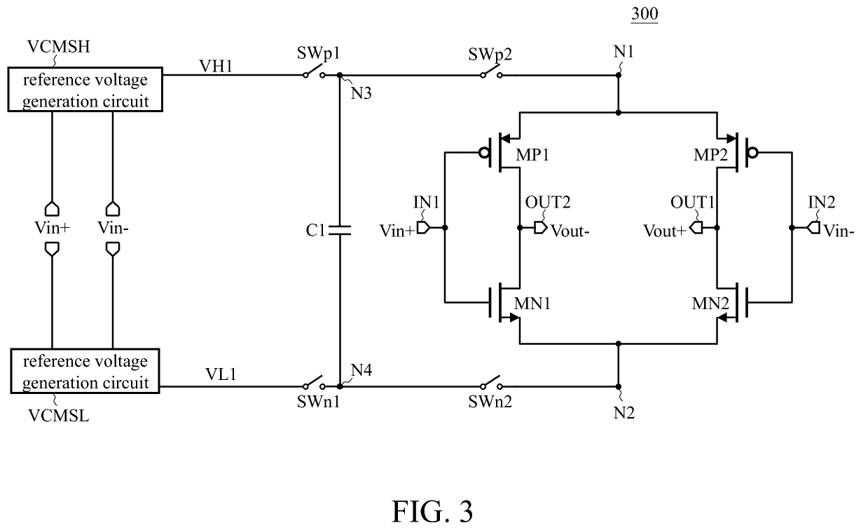

Reference is made to FIG. 3, which is a circuit diagram of an amplifier circuit according to another embodiment of the present invention. The amplifier circuit 300 is a type of dynamic amplifier. The amplifier circuit 300 is similar to the amplifier circuits 100 and 200, except that the reference voltage generation circuits VCMSH and VCMSL respectively generate the reference voltages VH1 and VL1 according to the common-mode voltage Vcmi of the input voltage Vin+ and the input voltage Vin−. This stabilizes the source-gate voltages of the transistors MP1 and MP2 and the gate-source voltages of the transistors MN1 and MN2, thereby improving the reliability and stability of the amplifier circuit 300. In other words, compared with the amplifier circuits 100 and 200, the amplifier circuit 300 is less susceptible to changes in the common-mode voltage Vcmi.

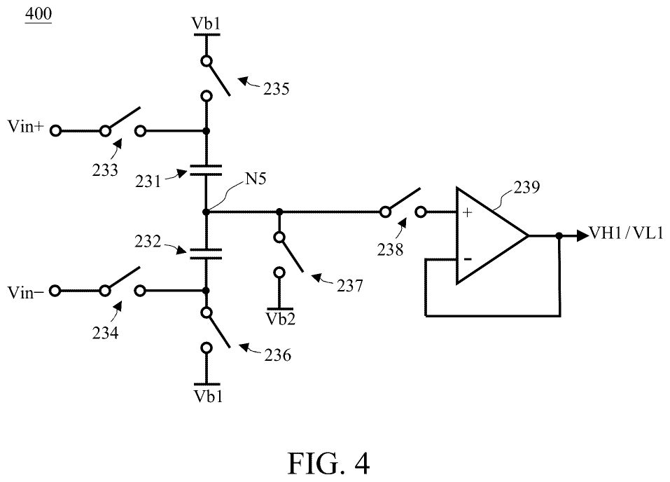

Reference is made to FIG. 4, which is a circuit diagram of the reference voltage generation circuit according to an embodiment of the present invention. The reference voltage generation circuit 400 includes a capacitor 231, a capacitor 232, a switch 233, a switch 234, a switch 235, a switch 236, a switch 237, a switch 238, and an operational amplifier 239.

One terminal of the capacitor 231 is coupled or electrically connected to the node N5; the other terminal of the capacitor 231 is coupled to the input voltage Vin+ through the switch 233 and coupled to the reference voltage Vb1 through the switch 235.

One terminal of the capacitor 232 is coupled or electrically connected to the node N5; the other terminal of the capacitor 232 is coupled to the input voltage Vin− through the switch 234 and coupled to the reference voltage Vb1 through the switch 236.

One terminal of the switch 237 is coupled or electrically connected to the reference voltage Vb2; another terminal of the switch 237 is coupled or electrically connected to the node N5.

The non-inverting input terminal of the operational amplifier 239 is coupled to the node N5 through the switch 238; the inverting input terminal of the operational amplifier 239 is coupled or electrically connected to the output terminal of the operational amplifier 239; the operational amplifier 239 outputs the reference voltage VH1 or the reference voltage VL1 from its output terminal.

The reference voltage generation circuit 400 operates according to a clock. When the clock is at the second level, the switches 233, 234, and 238 are turned off, and the switches 235, 236, and 237 are turned on. During this time, the operational amplifier 239 is idle.

When the clock is at the first level, the switches 233, 234, and 238 are turned on, and the switches 235, 236, and 237 are turned off. During this time, the output voltage of the operational amplifier 239 (i.e., the reference voltage VH1 or the reference voltage VL1) is substantially equal to Vcmi+Vb2−Vb1. That is to say, the reference voltage VH1 and/or the reference voltage VL1 can track the common-mode voltage Vcmi.

The aforementioned reference voltage generation circuits VCMSH and VCMSL may be embodied by the reference voltage generation circuit 400. The reference voltage VH1 and/or the reference voltage VL1 is adjusted by adjusting the DC voltage (Vb2−Vb1).

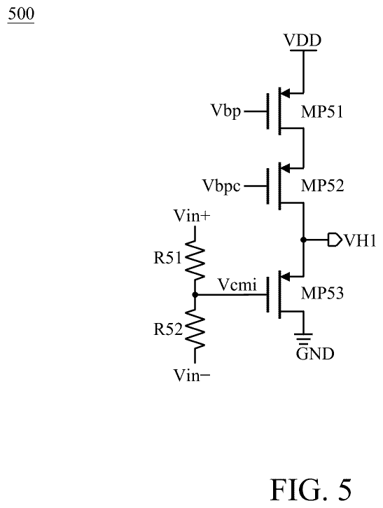

Reference is made to FIG. 5, which is a circuit diagram of the reference voltage generation circuit according to another embodiment of the present invention. The reference voltage generation circuit 500 includes a transistor MP51, a transistor MP52, a transistor MP53, a resistor R51, and a resistor R52.

The transistors MP51, MP52, and MP53 are all PMOS transistors and connected in series between the reference voltage VDD and the reference voltage GND (VDD>GND). The gate of the transistor MP51 receives a voltage Vbp; the gate of the transistor MP52 receives a voltage Vbpc; and the gate of the transistor MP53 receives the common-mode voltage Vcmi of the input voltages Vin+ and Vin−.

One terminal of the resistor R51 is coupled or electrically connected to the input voltage Vin+; the other terminal of the resistor R51 is coupled or electrically connected to the gate of the transistor MP53. One terminal of the resistor R52 is coupled or electrically connected to the input voltage Vin−; the other terminal of the resistor R52 is coupled or electrically connected to the gate of the transistor MP53.

The reference voltage generation circuit 500 is a source follower; therefore, the reference voltage VH1 varies with the common-mode voltage Vcmi. As the operating principle of source followers is well known to people having ordinary skill in the art, the details are omitted for brevity. The reference voltage generation circuit 500 can be used to implement the above-mentioned reference voltage generation circuit VCMSH.

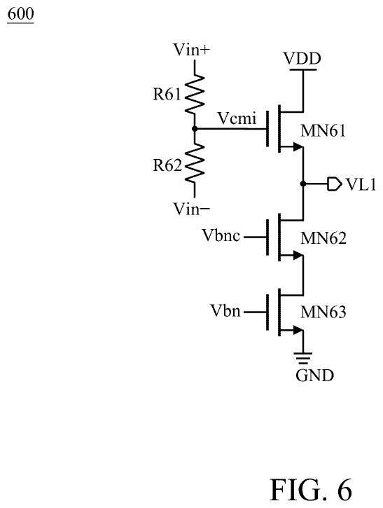

Reference is made to FIG. 6, which is a circuit diagram of the reference voltage generation circuit according to another embodiment of the present invention. The reference voltage generation circuit 600 includes a transistor MN61, a transistor MN62, a transistor MN63, a resistor R61, and a resistor R62.

The transistors MN61, MN62, and MN63 are all NMOS transistors and connected in series between the reference voltage VDD and the reference voltage GND. The gate of the transistor MN61 receives the common-mode voltage Vcmi of the input voltages Vin+ and Vin−; the gate of the transistor MN62 receives a voltage Vbnc; and the gate of the transistor MN63 receives a voltage Vbn.

One terminal of the resistor R61 is coupled or electrically connected to the input voltage Vin+; the other terminal of the resistor R61 is coupled or electrically connected to the gate of the transistor MN61. One terminal of the resistor R62 is coupled or electrically connected to the input voltage Vin−; the other terminal of the resistor R62 is coupled or electrically connected to the gate of the transistor MN61.

The reference voltage generation circuit 600 is a source follower; therefore, the reference voltage VL1 varies with the common-mode voltage Vcmi. The reference voltage generation circuit 600 can be used to implement the above-mentioned reference voltage generation circuit VCMSL.

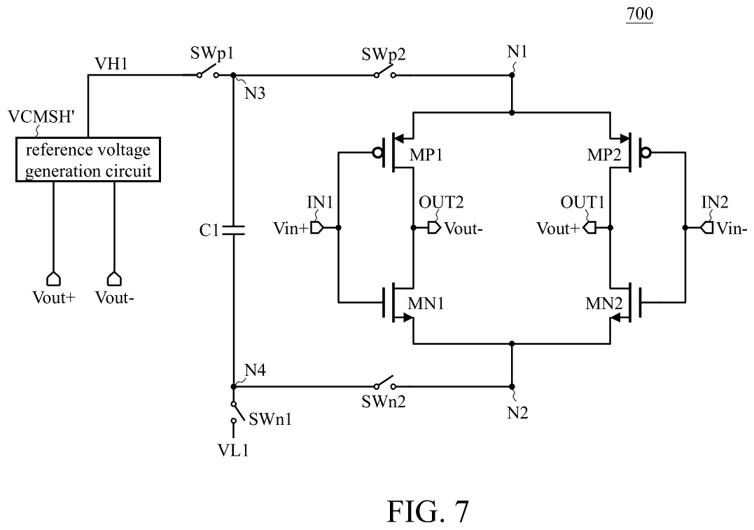

Reference is made to FIG. 7, which is a circuit diagram of an amplifier circuit according to another embodiment of the present invention. The amplifier circuit 700 is similar to the amplifier circuit 100, except that the reference voltage generation circuit VCMSH′ is used to detect the common-mode voltage Vcmo of the output voltages Vout+ and Vout−, and generates the reference voltage VH1 according to the common-mode voltage Vcmo. More specifically, when the common-mode voltage Vcmo of the output voltages Vout+ and Vout− decreases, the reference voltage generation circuit VCMSH′ generates a greater reference voltage VH1. When the common-mode voltage Vcmo of the output voltages Vout+ and Vout− increases, the reference voltage generation circuit VCMSH′ generates a smaller reference voltage VH1. A greater (or smaller) reference voltage VH1 can enhance (or reduce) the conduction capabilities of the transistors MP1 and MP2, leading to an increase (or decrease) in the common-mode voltage Vcmo. In other words, the amplifier circuit 700 is less susceptible to changes in the common-mode voltage Vcmo, leading to an enhancement in the reliability and stability of the amplifier circuit 700.

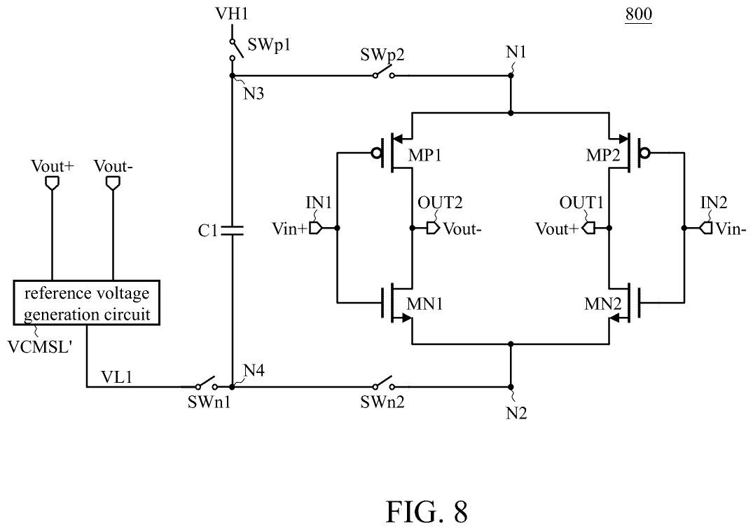

Reference is made to FIG. 8, which is a circuit diagram of an amplifier circuit according to another embodiment of the present invention. The amplifier circuit 800 is similar to the amplifier circuit 200, except that the reference voltage generation circuit VCMSL′ is used to detect the common-mode voltage Vcmo of the output voltages Vout+ and Vout−, and generate the reference voltage VL1 according to the common-mode voltage Vcmo. More specifically, when the common-mode voltage Vcmo of the output voltages Vout+ and Vout− decreases, the reference voltage generation circuit VCMSH′ generates a greater reference voltage VL1. When the common-mode voltage Vcmo of the output voltages Vout+ and Vout− increases, the reference voltage generation circuit VCMSH′ generates a smaller reference voltage VL1. A greater (or smaller) reference voltage VL1 can reduce (or enhance) the conduction capabilities of the transistors MN1 and MN2, leading to an increase (or decrease) in the common-mode voltage Vcmo. In other words, the amplifier circuit 800 is less susceptible to changes in the common-mode voltage Vcmo, leading to an enhancement in the reliability and stability of the amplifier circuit 800.

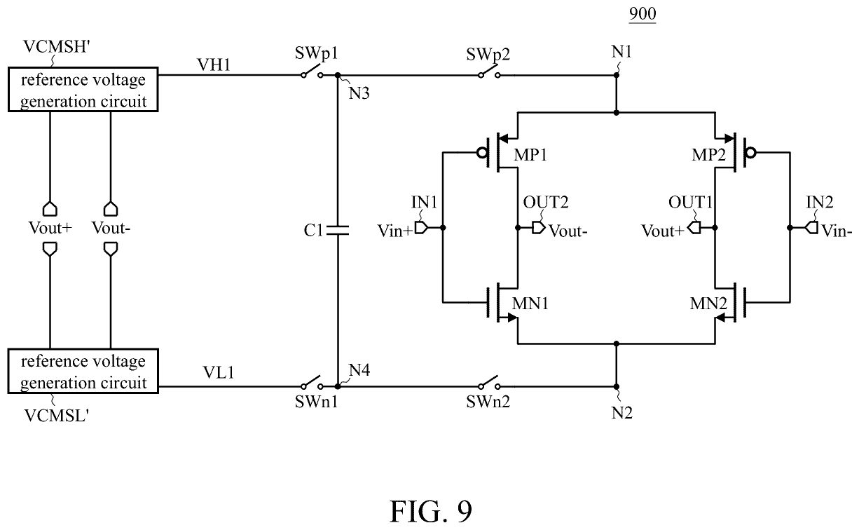

Reference is made to FIG. 9, which is a circuit diagram of an amplifier circuit according to another embodiment of the present invention. The amplifier circuit 900 is similar to the amplifier circuits 700 and 800, except that the reference voltage generation circuits VCMSH′ and VCMSL′ respectively generate the reference voltages VH1 and VL1 according to the common-mode voltage Vcmo. This stabilizes the common-mode voltage Vcmo of the output terminals (the output terminals OUT1 and OUT2), thereby improving the reliability and stability of the amplifier circuit 900. That is to say, compared to the amplifier circuits 700 and 800, the amplifier circuit 900 is less susceptible to changes in the common-mode voltage Vcmo.

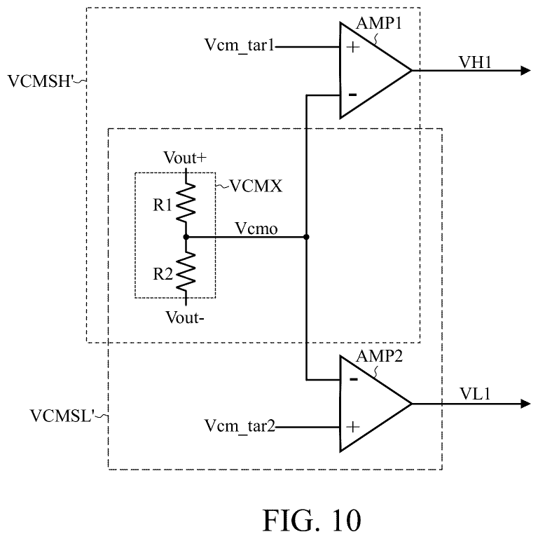

Reference is made to FIG. 10, which is a circuit diagram of the reference voltage generation circuits VCMSH′ and VCMSL′ according to an embodiment. The reference voltage generation circuit VCMSH′ includes a common-mode voltage detection circuit VCMX and an amplifier AMP1. The reference voltage generation circuit VCMSL′ includes the common-mode voltage detection circuit VCMX and an amplifier AMP2.

The common-mode voltage detection circuit VCMX includes resistors R1 and R2. The common-mode voltage detection circuit VCMX is coupled to the output terminals OUT1 and OUT2, and generates the common-mode voltage Vcmo of the output voltages Vout+ and Vout− according to the output voltages Vout+ and Vout−.

The amplifier AMP1 is coupled to the common-mode voltage detection circuit VCMX. The inverting input terminal of the amplifier AMP1 receives the common-mode voltage Vcmo; the non-inverting input terminal of the amplifier AMP1 receives a target voltage Vcm_tar1; the output terminal of the amplifier AMP1 outputs the reference voltage VH1. The amplifier AMP2 is coupled to the common-mode voltage detection circuit VCMX. The inverting input terminal of the amplifier AMP2 receives the common-mode voltage Vcmo; the non-inverting input terminal of the amplifier AMP2 receives a target voltage Vcm_tar2; the output terminal of the amplifier AMP2 outputs the reference voltage VL1. The target voltage Vcm_tar1 may or may not be equal to the target voltage Vcm_tar2.

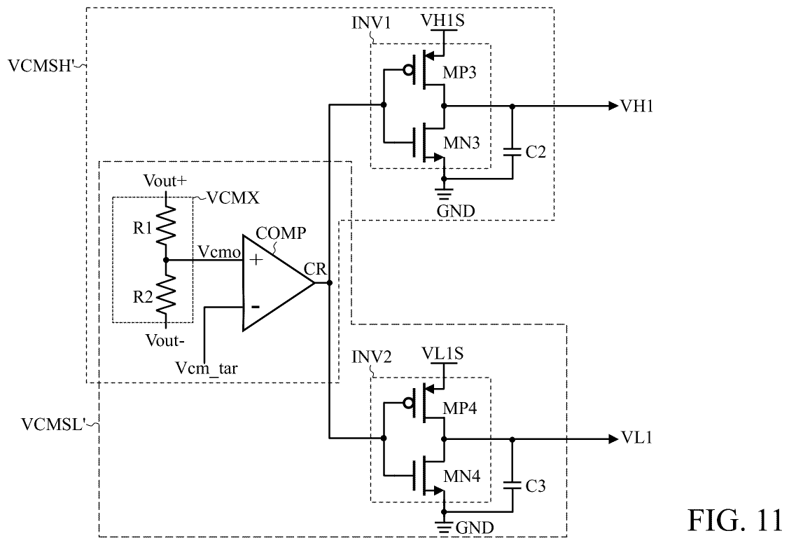

Reference is made to FIG. 11, which is a circuit diagram of the reference voltage generation circuits VCMSH′ and VCMSL′ according to another embodiment. The reference voltage generation circuit VCMSH′ includes the common-mode voltage detection circuit VCMX, a comparator COMP, an inverter INV1, and a capacitor C2. The reference voltage generation circuit VCMSL′ includes the common-mode voltage detection circuit VCMX, the comparator COMP, an inverter INV2, and a capacitor C3.

The comparator COMP is coupled to the common-mode voltage detection circuit VCMX and is used to compare the common-mode voltage Vcmo with a target voltage Vcm_tar to generate a comparison result CR.

The inverter INV1, coupled between a reference voltage VH1S and the reference voltage GND and coupled to the comparator COMP, includes a transistor MP3 and a transistor MN3. One terminal of the capacitor C2 is coupled or electrically connected to the drain of the transistor MP3 and the drain of the transistor MN3; the other terminal of the capacitor C2 is coupled or electrically connected to the reference voltage GND. In reference to both FIGS. 9 and 11, because the switch SWp1 receives the reference voltage VH1, the capacitor C2 is coupled between the switch SWp1 and the reference voltage GND.

The inverter INV2, coupled between a reference voltage VL1S and the reference voltage GND and coupled to the comparator COMP, includes a transistor MP4 and a transistor MN4. One terminal of the capacitor C3 is coupled or electrically connected to the drain of the transistor MP4 and the drain of the transistor MN4; the other terminal of the capacitor C3 is coupled or electrically connected to the reference voltage GND. In reference to both FIGS. 9 and 11, because the switch SWn1 receives the reference voltage VL1, the capacitor C3 is coupled between the switch SWn1 and the reference voltage GND.

Reference is made to FIGS. 9 and 11. When the common-mode voltage Vcmi of the input voltages Vin+ and Vin− exceeds a designed value (which indicates a decrease in the conduction capabilities of the transistors MP1 and MP2 and an increase in the conduction capabilities of the transistors MN1 and MN2), the common-mode voltage Vcmo of the output voltages Vout+ and Vout− decreases. When the common-mode voltage Vcmo of the output voltages Vout+ and Vout− is lower than the target voltage Vcm_tar, the comparison result CR is 0, causing the reference voltages VH1 and VL1 to approach the reference voltages VH1S and VL1S respectively. In other words, when the common-mode voltage Vcmo of the output voltages Vout+ and Vout− decreases, the reference voltages VH1 and VL1 increase. This results in an increase in the conduction capabilities of the transistors MP1 and MP2 and a decrease in the conduction capabilities of the transistors MN1 and MN2, leading to an increase in the common-mode voltage Vcmo of the output voltages Vout+ and Vout−.

Similarly, when the common-mode voltage Vcmo of the output voltages Vout+ and Vout− increases, the reference voltages VH1 and VL1 decrease. This results in a decrease in the conduction capabilities of the transistors MP1 and MP2 and an increase in the conduction capabilities of the transistors MN1 and MN2, leading to a decrease in the common-mode voltage Vcmo of the output voltages Vout+ and Vout−.

In summary, because the amplifier circuit of the present invention is less susceptible to common-mode voltage disturbances, its performance (e.g., reliability and stability) is improved.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An amplifier circuit having a first input terminal, a second input terminal, a first output terminal, a second output terminal, a first node, a second node, a third node, and a fourth node, and receiving a first input voltage and a second input voltage respectively through the first input terminal and the second input terminal, the amplifier circuit comprising:
a first transistor having a first terminal, a second terminal, and a first control terminal, wherein the first terminal is coupled to the first node, the second terminal is coupled to the second output terminal, and the first control terminal is coupled to the first input terminal;
a second transistor having a third terminal, a fourth terminal, and a second control terminal, wherein the third terminal is coupled to the second node, the fourth terminal is coupled to the second output terminal, and the second control terminal is coupled to the first input terminal;
a third transistor having a fifth terminal, a sixth terminal, and a third control terminal, wherein the fifth terminal is coupled to the first node, the sixth terminal is coupled to the first output terminal, and the third control terminal is coupled to the second input terminal;
a fourth transistor having a seventh terminal, an eighth terminal, and a fourth control terminal, wherein the seventh terminal is coupled to the second node, the eighth terminal is coupled to the first output terminal, and the fourth control terminal is coupled to the second input terminal;
a first capacitor having a ninth terminal and a tenth terminal, wherein the ninth terminal is coupled to the third node, and the tenth terminal is coupled to the fourth node;
a first switch coupled between the third node and a first reference voltage;
a second switch coupled between the fourth node and a second reference voltage;
a third switch coupled between the first node and the third node;
a fourth switch coupled between the second node and the fourth node; and
a reference voltage generation circuit coupled to the first input terminal and the second input terminal and configured to generate at least one of the first reference voltage and the second reference voltage according to the first input voltage and the second input voltage.

2. The amplifier circuit of claim 1, wherein the reference voltage generation circuit extracts a common-mode voltage of the first input voltage and the second input voltage and generates at least one of the first reference voltage and the second reference voltage according to the common-mode voltage.

3. The amplifier circuit of claim 2, wherein the reference voltage generation circuit is a first reference voltage generation circuit, and the first reference voltage generation circuit generates the first reference voltage according to the common-mode voltage, the amplifier circuit further comprises:
a second reference voltage generation circuit coupled to the first input terminal and the second input terminal and configured to generate the second reference voltage according to the common-mode voltage.

4. An amplifier circuit having a first input terminal, a second input terminal, a first output terminal, a second output terminal, a first node, a second node, a third node, and a fourth node, and outputting a first output voltage and a second output voltage respectively through the first output terminal and the second output terminal, the amplifier circuit comprising:
a first transistor having a first terminal, a second terminal, and a first control terminal, wherein the first terminal is coupled to the first node, the second terminal is coupled to the second output terminal, and the first control terminal is coupled to the first input terminal;
a second transistor having a third terminal, a fourth terminal, and a second control terminal, wherein the third terminal is coupled to the second node, the fourth terminal is coupled to the second output terminal, and the second control terminal is coupled to the first input terminal;
a third transistor having a fifth terminal, a sixth terminal, and a third control terminal, wherein the fifth terminal is coupled to the first node, the sixth terminal is coupled to the first output terminal, and the third control terminal is coupled to the second input terminal;
a fourth transistor having a seventh terminal, an eighth terminal, and a fourth control terminal, wherein the seventh terminal is coupled to the second node, the eighth terminal is coupled to the first output terminal, and the fourth control terminal is coupled to the second input terminal;
a first capacitor having a ninth terminal and a tenth terminal, wherein the ninth terminal is coupled to the third node, and the tenth terminal is coupled to the fourth node;
a first switch coupled between the third node and a first reference voltage;
a second switch coupled between the fourth node and a second reference voltage;
a third switch coupled between the first node and the third node;
a fourth switch coupled between the second node and the fourth node; and
a reference voltage generation circuit coupled to the first output terminal and the second output terminal and configured to generate at least one of the first reference voltage and the second reference voltage according to the first output voltage and the second output voltage.

5. The amplifier circuit of claim 4, wherein the reference voltage generation circuit extracts a common-mode voltage of the first output voltage and the second output voltage and generates at least one of the first reference voltage and the second reference voltage according to the common-mode voltage.

6. The amplifier circuit of claim 5, wherein the reference voltage generation circuit is a first reference voltage generation circuit, and the first reference voltage generation circuit generates the first reference voltage according to the common-mode voltage, the amplifier circuit further comprises:
a second reference voltage generation circuit coupled to the first output terminal and the second output terminal and configured to generate the second reference voltage according to the common-mode voltage.

7. The amplifier circuit of claim 6, wherein the first reference voltage generation circuit and the second reference voltage generation circuit together comprise:
a common-mode voltage detection circuit coupled to the first output terminal and the second output terminal and configured to generate the common-mode voltage according to the first output voltage and the second output voltage;
a first amplifier coupled to the common-mode voltage detection circuit and configured to generate the first reference voltage according to the common-mode voltage and a first target voltage; and
a second amplifier coupled to the common-mode voltage detection circuit and configured to generate the second reference voltage according to the common-mode voltage and a second target voltage.

8. The amplifier circuit of claim 6, wherein the first reference voltage generation circuit and the second reference voltage generation circuit together comprise:
a common-mode voltage detection circuit coupled to the first output terminal and the second output terminal and configured to generate the common-mode voltage according to the first output voltage and the second output voltage;
a comparator coupled to the common-mode voltage detection circuit and configured to generate a comparison result according to the common-mode voltage and a target voltage;
a first inverter coupled to the comparator and configured to generate the first reference voltage according to the comparison result;
a second capacitor coupled between the first switch and a third reference voltage;
a second inverter coupled to the comparator and configured to generate the second reference voltage according to the comparison result; and
a third capacitor coupled between the second switch and the third reference voltage.

9. The amplifier circuit of claim 5, wherein the reference voltage generation circuit comprises:
a common-mode voltage detection circuit coupled to the first output terminal and the second output terminal and configured to generate the common-mode voltage according to the first output voltage and the second output voltage; and
an amplifier coupled to the common-mode voltage detection circuit and configured to generate one of the first reference voltage and the second reference voltage according to the common-mode voltage and a target voltage.

10. The amplifier circuit of claim 5, wherein the reference voltage generation circuit comprises:
a common-mode voltage detection circuit coupled to the first output terminal and the second output terminal and configured to generate the common-mode voltage according to the first output voltage and the second output voltage;
a comparator coupled to the common-mode voltage detection circuit and configured to generate a comparison result according to the common-mode voltage and a target voltage;
an inverter coupled to the comparator and configured to generate one of the first reference voltage and the second reference voltage according to the comparison result; and
a second capacitor coupled between a third reference voltage and the first switch or the second switch.
